(19) United States
(12) Patent Application Publication
(10) Pub. No.: US 2019/0304957 A1
(43) Pub. Date: Oct. 3, 2019

(54) LIGHT EMITTING MODULE AND LIGHT EMITTING MODULE MANUFACTURING METHOD

(71) Applicant: TOSHIBA HOKUTO ELECTRONICS CORPORATION, Asahikawa-Shi (JP)

(72) Inventors: Yojiro YARIMIZU, Asahikawa (JP); Tsuyoshi Abe, Asahikawa (JP); Koichi Matsushita, Fujisawa (JP)

(73) Assignee: TOSHIBA HOKUTO ELECTRONICS CORPORATION, Asahikawa-Shi (JP)

(21) Appl. No.: 16/357,785

(22) Filed: Mar. 19, 2019

(30) Foreign Application Priority Data
Mar. 30, 2018 (JP) 2018-067686

(51) Int. Cl. H01L 25/075; H01L 23/538; H01L 33/48; H01L 33/54; H01L 33/62

(52) U.S. Cl. CPC H01L 25/0753; H01L 23/5387; H01L 33/483; H01L 2933/0066; H01L 33/62; H01L 2933/0033; H01L 2933/005; H01L 33/54

(57) ABSTRACT

A light emitting module according to an embodiment comprising: a first substrate having light transmissivity and flexibility; a conductor layer provided on a surface of the first substrate; a second substrate having light transmissivity and flexibility and placed so as to face the conductor layer; a light emitting element placed between the first substrate and the second substrate, and connected to the conductor layer; and a resin layer placed between the first substrate and the second substrate, and formed of a first resin and a second resin that have respective lowest melting viscosities different from each other.

### CROSS-REFERENCE TO RELATED APPLICATIONS

This application is based upon and claims the benefit of priority from Japanese Patent Application No. 2018-067686, filed on Mar. 30, 2018; the entire contents of which are incorporated herein by reference.

### FIELD

Embodiments described herein relate generally to a light emitting module and a light emitting module manufacturing method.

### BACKGROUND

In recent years, LEDs (Light Emitting Diodes) that have relatively little power consumption are getting attention as a next-generation light source. The LEDs are compact, have a little heat generation amount, and have an excellent response. Hence, LEDs are broadly applied for various optical apparatuses. In recent years, for example, a light emitting module that has a light source which is the LEDs placed on a flexible and translucent substrate has been proposed.

According to this kind of the light emitting module, a plurality of light emitting elements placed between a pair of transparent substrates are held by, for example, a transparent resin that is filled between the substrates. This maintains an electrical contact between a conductive circuit layer provided on the substrate and the light emitting elements.

The above-described light emitting module is manufactured by pressing while heating the substrates with the light emitting elements and the resin being placed between the pair of substrates. At this time, heating makes the resin softened and the softened resin is filled around the light emitting elements without a void. Next, when the resin is cured, the light emitting elements are surely held to the substrate.

When manufacturing the light emitting module by pressing, it is necessary to make the resin softened. Accordingly, some of the softened resin may flow out between the substrates when pressed. When the resin flows out during the pressing, the light emitting elements may be displaced together with the resin, and may be mispositioned.

### BRIEF DESCRIPTION OF THE DRAWINGS

FIG. 1 is a perspective view of a light emitting module according to an embodiment;

FIG. 2 is a side view illustrating an XZ surface of the light emitting module;

FIG. 3 is a diagram illustrating a part of a mesh pattern in an enlarged manner;

FIG. 4 is a side view illustrating a YZ surface of the light emitting module;

FIG. 5 is a perspective view of light emitting elements;

FIG. 6 is a diagram illustrating a viscosity of a resin;

FIG. 7 is a plan view of an assembly;

FIG. 8 is a diagram for describing a light emitting module manufacturing method;

FIG. 9 is a diagram for describing the light emitting module manufacturing method;

FIG. 10 is a diagram for describing the light emitting module manufacturing method;

FIG. 11 is a diagram for describing the light emitting module manufacturing method;

FIG. 12 is a diagram for describing the light emitting module manufacturing method;

FIG. 13 is a diagram for describing the light emitting module manufacturing method;

FIG. 14 is a diagram for describing the light emitting module manufacturing method;

FIG. 15 is a diagram for describing the light emitting module manufacturing method;

FIG. 16 is a diagram for describing the light emitting module manufacturing method;

FIG. 17 is a diagram for describing the light emitting module manufacturing method;

FIG. 18 is a perspective view of an evaluation model;

FIG. 19 is a cross-sectional view of the evaluation model;

FIG. 20 is an exploded perspective view of a sheet member;

FIG. 21 is a diagram for describing a viscosity of a dam member and that of an intermediate resin sheet;

FIG. 22 is a diagram illustrating an evaluation result by the evaluation model;

FIG. 23 is a diagram illustrating the evaluation result by the evaluation model;

FIG. 24 is a diagram for describing the light emitting module manufacturing method according to a modified example;

FIG. 25 is a diagram for describing the light emitting module manufacturing method according to a modified example;

FIG. 26 is a diagram for describing the light emitting module manufacturing method according to a modified example;

FIG. 27 is a diagram for describing the light emitting module manufacturing method according to a modified example;

FIG. 28 is a diagram for describing the light emitting module manufacturing method according to a modified example;

FIG. 29 is a diagram for describing the light emitting module manufacturing method according to a modified example;

FIG. 30 is a diagram for describing the light emitting module manufacturing method according to a modified example;

FIG. 31 is a diagram for describing the light emitting module manufacturing method according to a modified example; and

FIG. 32 is a diagram for describing the light emitting module manufacturing method according to a modified example.

### DETAILED DESCRIPTION

A light emitting module according to an embodiment comprising: a first substrate having light transmissivity and flexibility; a conductor layer provided on a surface of the first substrate; a second substrate having light transmissivity and flexibility and placed so as to face the conductor layer; a light emitting element placed between the first substrate and the second substrate, and connected to the conductor layer; and

a resin layer placed between the first substrate and the second substrate, and formed of a first resin and a second resin that have respective lowest melting viscosities different from each other.

A light emitting module manufacturing method according to an embodiment includes: forming a conductor layer at an one side of a first substrate having light transmissivity and flexibility; forming a surrounding layer that surrounds the conductor layer at the one side of the first substrate; forming a first resin layer at the one side of the first substrate using a first resin, the first resin layer being laminated on the conductor layer; placing light emitting elements on a surface of the first resin layer; placing a second substrate having light transmissivity and flexibility at the one side of the first substrate; and performing thermal press of heating the first substrate and the second substrate to a melting temperature at which the first resin melts, and of pressing the first substrate and the second substrate against each other.

An embodiment according to the present disclosure will be described with reference to figures. An XYZ coordinate system that has an X-axis, a Y-axis, and a Z-axis which intersect perpendicularly to each other will be applied for description.

<Structure>

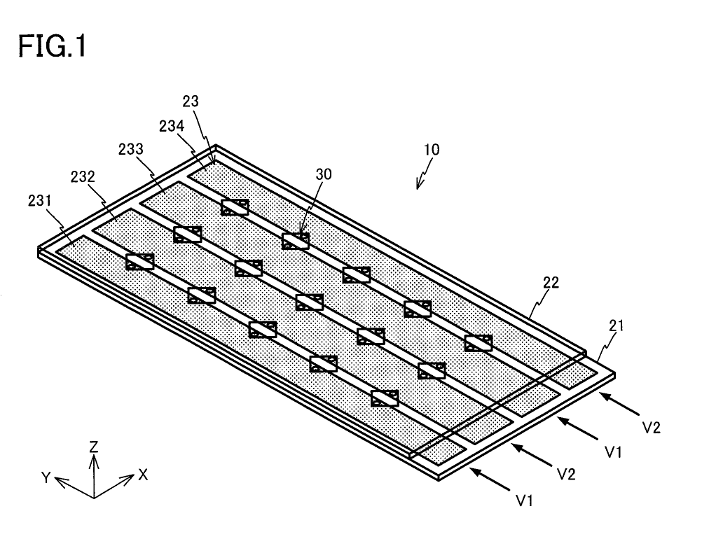

FIG. 1 is a perspective view of a light emitting module 10 according to this embodiment. As illustrated in FIG. 1, the light emitting module 10 is a rectangular module that has a lengthwise direction parallel to the Y-axis direction. The light emitting module 10 is flexible and light transmissive.

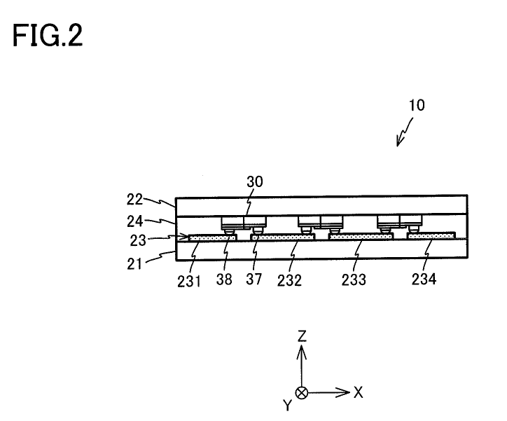

FIG. 2 is a side view illustrating an XZ side of the light emitting module 10. As illustrated in FIG. 2, the light emitting module 10 includes a pair of films 21 and 22, a plurality of light emitting elements 30 and a resin layer 24. The plurality of light emitting elements 30 and the resin layer 24 are placed between the pair of films 21 and 22.

The films 21 and 22 are each a rectangular film that has an electrical insulation, and has a lengthwise direction parallel to the Y-axis direction. The films 21 and 22 each have a thickness of substantially 50 to 300 μm, and are light transmissive to visible light. It is preferable that a total light transmittance of the films 21 and 22 should be equal to or higher than 90%. Note that the term total light transmittance means the total light transmittance measured based on Japanese Industrial Standards, JIS K7375: 2008.

The films 21 and 22 are flexible, and the bending elastic modulus thereof is substantially 0 to 320 kgf/mm² (excluding zero). Note that the term elastic modulus is a value measured by a method in compliance with ISO 178 (JIS K7171: 2008).

Example materials applicable for the films 21 and 22 are polyethylene terephthalate (PET), polyethylene naphthalate (PEN), polycarbonate (PC), polyethylene succinate (PES), arton (ARTON), and an acrylic resin, etc.

A conductor layer 23 that has a thickness of substantially 0.05 to 10 μm is formed on the upper surface (the surface at the +Z-side in FIG. 2) of the film 21 in the pair of the films 21 and 22. The conductor layer 23 is, for example, a plating film, a vapor deposition film, or a sputter film. Moreover, the conductor layer 23 may be a metal film pasted by an adhesive. When the conductor layer 23 is a vapor deposition film or a sputter film, the thickness of the conductor layer 23 is substantially 0.05 to 2 μm. When the conductor layer 23 is a metal film, the thickness of the conductor layer 23 is substantially 2 to 10 μm or substantially 2 to 7 μm.

As illustrated in FIG. 1, the conductor layer 23 includes rectangular mesh patterns 231 to 234 that have the lengthwise direction parallel to the Y-axis direction. Each of the mesh patterns 231 to 234 is formed of a metal material, such as copper (Cu) or silver (Ag).

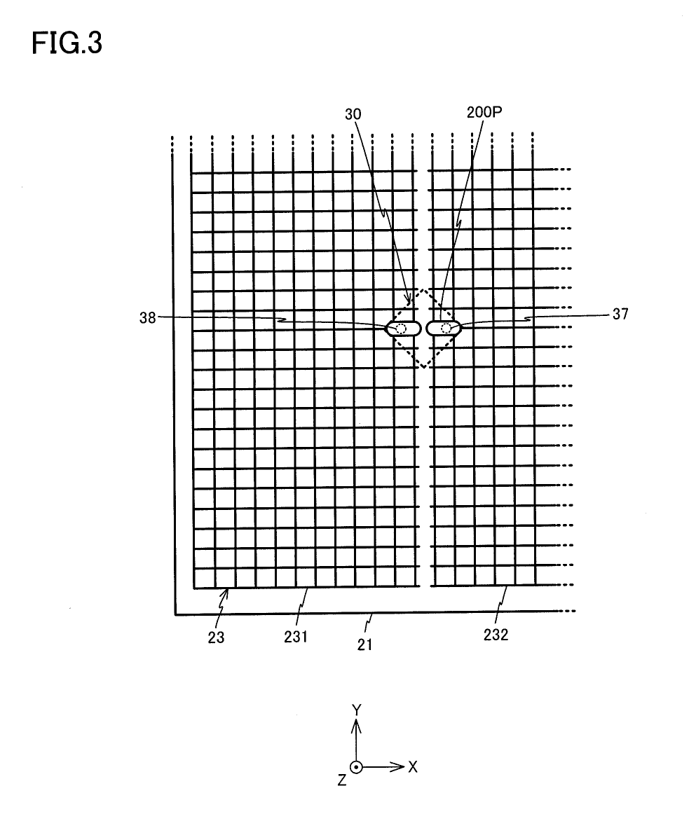

FIG. 3 is a diagram illustrating a part of the mesh patterns 231 and 232 in an enlarged manner. As is clear from FIG. 3, the mesh patterns 231 to 234 are each a line pattern that has a width of substantially 10 μm. The line patterns parallel to the X-axis direction are formed at a pitch of substantially 300 μm along the Y-axis direction. Moreover, the line patterns parallel to the Y-axis direction are formed at a pitch of substantially 300 μm along the X-axis direction. Connection pads 200P to which the electrodes of the light emitting elements 30 are respectively connected are formed in the respective mesh patterns 231 to 234.

It is preferable that the total light transmissivity (e.g., JIS K7105) of each of the mesh patterns 231 to 234 should be within a range between 10 and 85%.

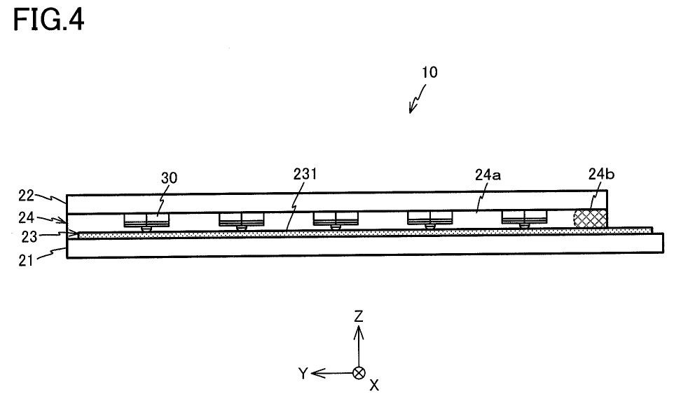

FIG. 4 is a side view illustrating an YZ surface of the light emitting module 10. As illustrated in FIG. 4, the film 21 has a longer length in the Y-axis direction than that of the film 22. Hence, the conductor layer 23 formed at the −Y-side end of the film 21 is exposed from the −Y-side of the film 22.

The light emitting element 30 is a square LED chip which has a thickness of substantially 70 to 160 μm, and which has a side of substantially 0.1 to 3 mm. For example, the thickness of the light emitting element which emits red light is 75 to 125 μm. The thickness of the light emitting element which emits blue or green is 80 to 100 μm. The light emitting element 30 is, for example, a bare chip.

FIG. 5 is a perspective view of the light emitting element 30. As illustrated in FIG. 5, the light emitting element 30 is an LED chip that includes a base substrate 31, an N-type semiconductor layer 32, an active layer 33, and a P-type semiconductor layer 34. The rated current of the light emitting element 30 is substantially 50 mA.

The base substrate 31 is, for example, a substrate in a square plate shape and formed of sapphire. The N-type semiconductor layer 32 that is in the same shape as that of the base substrate 31 is formed on the upper surface of the base substrate 31. Moreover, the active layer 33 and the P-type semiconductor layer 34 are laminated in sequence on the upper surface of the N-type semiconductor layer 32. The N-type semiconductor layer 32, the active layer 33, and the P-type semiconductor layer 34 are each formed of a compound semiconductor material. For example, as for a light emitting element that emits red light, an InAlGaP-based semiconductor is applicable as the active layer. Moreover, as for a light emitting element that emits blue or green light, a GaN-based semiconductor is applicable as the P-type semiconductor layer 34 and the N-type semiconductor layer 32, and an InGaN-based semiconductor is applicable as the active layer 33. In any cases, the active layer may be a double-hetero (DH) junction structure, or a multiple quantum well (MQW) structure. Moreover, a PN-junction structure is applicable.

The active layer 33 and the P-type semiconductor layer 34 laminated on the N-type semiconductor layer 32 are provided with notches at the −X side and −Y side corners. The surface of the N-type semiconductor layer 32 is exposed from the notches of the active layer 33 and P-type semiconductor layer 34.

A pad 36 that is electrically connected to the N-type semiconductor layer 32 is formed in the region of the N-type semiconductor layer 32 where the active layer 33 and the P-type semiconductor layer 34 are exposed. Moreover, a pad 35 that is electrically connected to the P-type semiconductor layer 34 is formed at the +X side and +Y side of the corner of the P-type semiconductor layer 34. The pads 35 and 36 are each formed of copper (Cu) or gold (Au), and respective bumps 37 and 38 are formed on the respective upper surfaces. The bumps 37 and 38 are each formed of a metal bump, such as gold (Au) or a gold alloy. A solder bump formed in a semispherical shape may be applied instead of the metal bump. According to the light emitting element 30, the bump 37 serves as a cathode electrode, while the bump 38 serves as an anode electrode.

It is preferable that the melting point of the bumps 37 and 38 should be equal to or higher than 180° C. Moreover, it is further preferable that the melting point of the bumps 37 and 38 should be equal to or higher than 200° C. When the melting point of the bumps 37 and 38 is lower than 180° C., the bumps 37 and 38 may be deformed during the thermal press in the manufacturing process of the light emitting module 10.

As is clear from FIG. 3, the light emitting element 30 is placed across the two mesh patterns by having the bumps 37 and 38 connected to the respective connection pads 200P formed in the two of the mesh patterns 231 to 234. As illustrated in FIG. 2, according to the light emitting module 10, for example, the bump 38 is connected to the mesh patterns 231 and 233, and the bump 37 is connected to the mesh pattern 232 and 234.

The resin layer 24 is transmissive to visible light, and as illustrated in FIG. 4, is formed between the films 21 and 22. The resin layer 24 is formed of two kinds of resins that are a resin 24a and a resin 24b.

The resin 24a is formed of a resin material that has characteristics satisfying predetermined conditions, such as the lowest melt viscosity prior to curing, a temperature at the lowest melt viscosity prior to curing, a melt viscosity change rate until reaching a temperature at the lowest melt viscosity, a vicat softening temperature after curing, a tensile storage elastic modulus after curing, and a glass transition temperature after curing.

The resin 24a according to this embodiment is formed of a thermosetting resin like an epoxy-based resin. The thermosetting resin that forms the resin layer 24 has a lowest melt viscosity VC1 prior to curing within a range between 10 to 10000 Pa·s within a temperature range of 80 to 160° C. Moreover, a melt viscosity change rate VR until reaching a temperature TL (a softest temperature) in the lowest melt viscosity VC1 prior to curing is equal to or lower than 1/1000 (equal to or lower than thousandth). The resin layer 24 cured after the viscosity becomes the lowest melt viscosity by heating has a vicat softening temperature TP within a range between 80 to 160° C., and has a tensile storage elastic modulus EM within a range between 0.01 to 1000 GPa at a temperature range between 0 to 100° C. Moreover, a glass transition temperature TG of the resin 24 is 100 to 160° C.

The physical property values of thermosetting resin are, for example, as follows.

Lowest melt viscosity VC1: 10 to 10000 Pa·s

Temperature TL (softest temperature) at lowest melt viscosity VC1: 80 to 160° C.

Melt viscosity change rate VR until reaching temperature TL: equal to or lower than 1/1000

Vicat softening temperature TP: 80 to 160° C.

Tensile storage elastic modulus EM: 0.01 to 1000 GPa between 0 to 100° C.

Glass transition temperature TG: 100 to 160° C.

Note that regarding the melt viscosity measurement, values were obtained by changing the temperature of the measuring object between 50 to 180° C. in accordance with the scheme defined in JIS K7233. The vicat softening temperature was a value obtained under a condition in which a test load was 10 N and a temperature rise rate was 50° C./hour in accordance with A 50 defined in JIS K7206 (ISO 306: 2004). The glass transition temperature and the melting temperature were values obtained by differential scanning calorimetry through a scheme in compliance with JIS K7121 (ISO 3146). The tensile storage elastic modulus was a value obtained through a scheme in compliance with JIS K7244-1 (ISO 6721). More specifically, this is the value obtained by performing sampling on the measuring object subjected to a uniform temperature rise 1° C. by 1° C. per a minute from −100° C. to 200° C. at a frequency of 10 Hz using a dynamic viscosity automatic measuring instrument.

The resin 24a is formed of a material that contains a primary component which is a thermosetting resin. Moreover, other resin components, etc., may be contained as needed. Example resins applied as the material of the resin 24a are an epoxy-based resin, an acrylic resin, a styrene-based resin, an ester-based resin, an urethane-based resin, a melamine resin, a phenol resin, an unsaturated polyester resin, and a diallyl phthalate resin. Among those resins, since the epoxy-based resin has excellent flowability when softened, adhesiveness after cured, and an antiweatherability, etc., in addition to the transmissivity, the electrical insulation, and the flexibility, etc., thus suitable as the material of the resin layer 24. Needless to say, the resin layer 24 may be formed of other resins than the epoxy-based resin.

The resin 24b is also formed of a material that contains a primary component which is a thermosetting resin like the resin 24a. The resin 24b may also contain other resin components as needed. An example material of the resin 24b is a polyester-based resin. The resin 24b has the lowest viscosity that is higher than VC1 (10 to 10000 Pa·s) which is different from the resin 24a.

The resin 24a is filled around the pads 35 and 36 of the light emitting element 30, and the bumps 37 and 38 without a void. Moreover, the resin 24b is placed along the outer edge of the film 22 at the −Y-side.

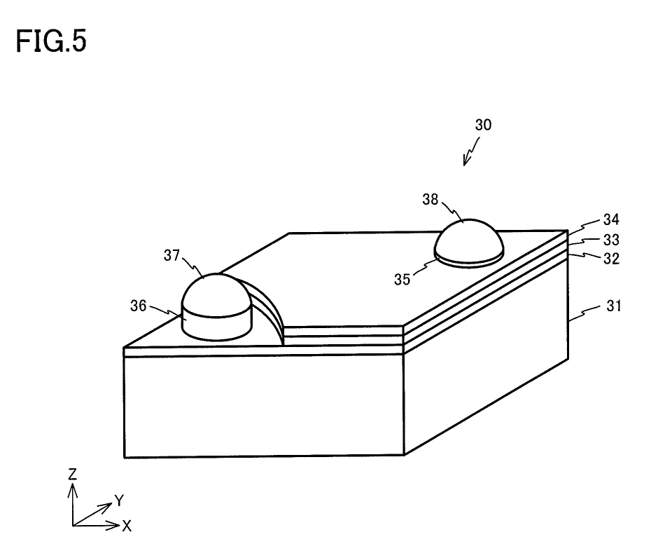

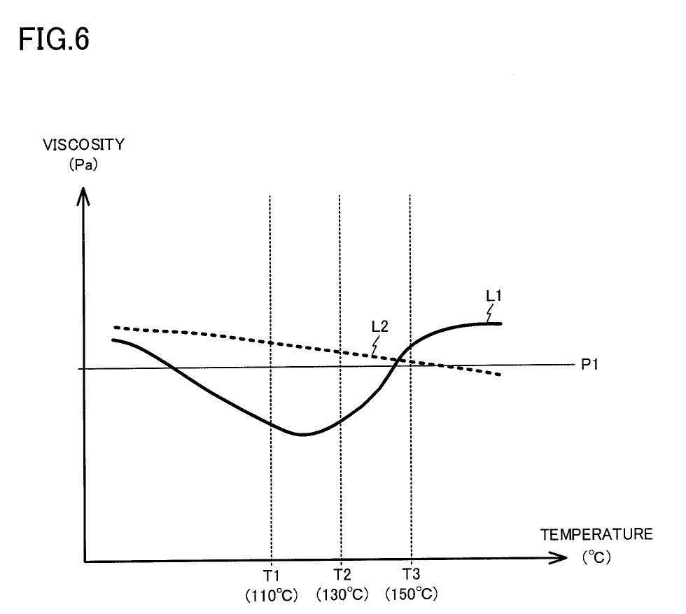

FIG. 6 is a diagram illustrating the viscosities of the resins 24a and 24b. A curved line L1 in FIG. 6 indicates the viscosity of the resin 24a. Moreover, a curved line L2 indicates the viscosity of the resin 24b. As illustrated in FIG. 6, a point (softest point) at which the viscosity of the resin 24a becomes the minimum is located between a temperature T1 and a temperature T3. The temperature T1 is substantially 110° C., and the temperature T3 is substantially 150° C. Moreover, the viscosity of the resin 24b does not become lower than P1 between the temperature T1 and the temperature T3. P1 is a value at which the resin does not flow, and is substantially 1.0×10⁴ (Pa).

According to the light emitting module 10 that employs the structure as described above, the light emitting elements 30 emit lights by applying different voltages V1 and V2 to the adjoining two mesh patterns among 231 to 234 as illustrated in FIG. 1.

<Manufacturing Method>

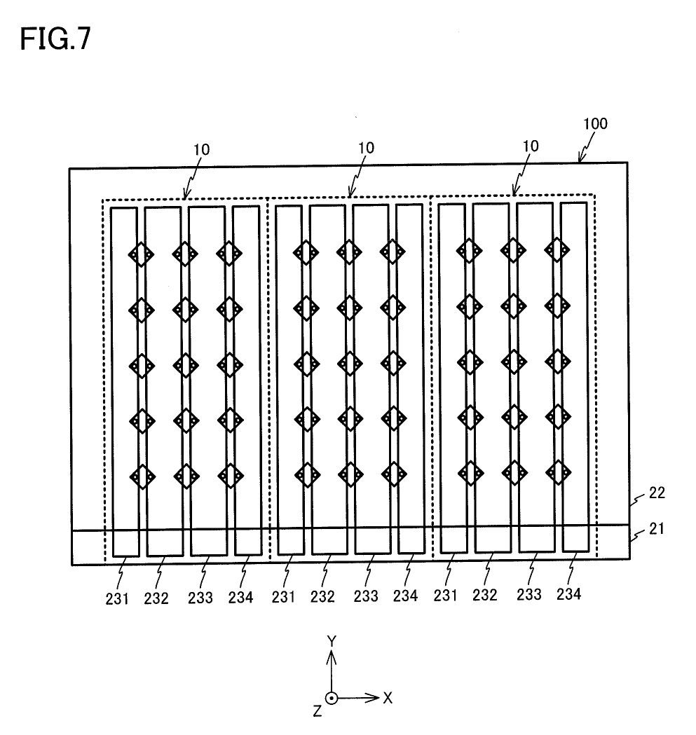

Next, a manufacturing method of the light emitting module 10 will be described. As illustrated in FIG. 7, the manufacturing of the light emitting module 10 is performed to form an assembly 100 of the light emitting modules 10 that share the common films 21 and 22, etc., and to cut out the light emitting module 10 from the assembly 100.

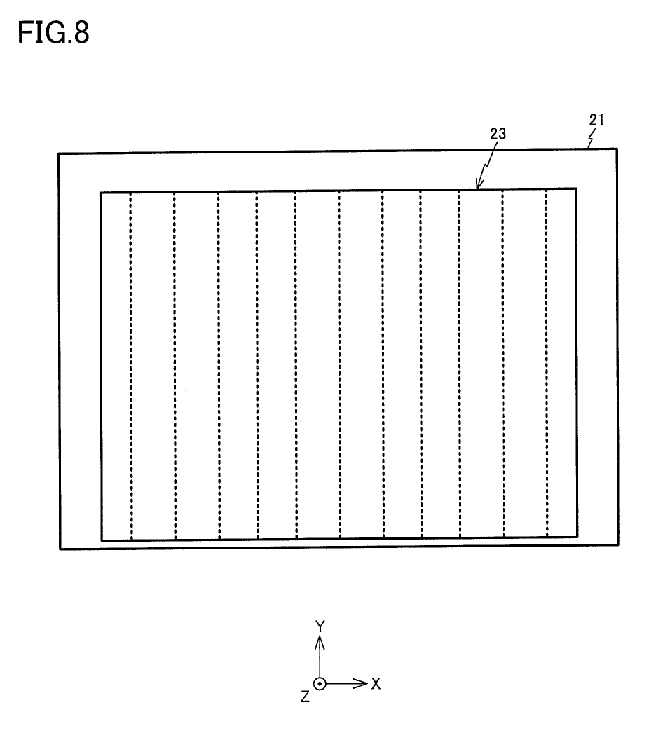

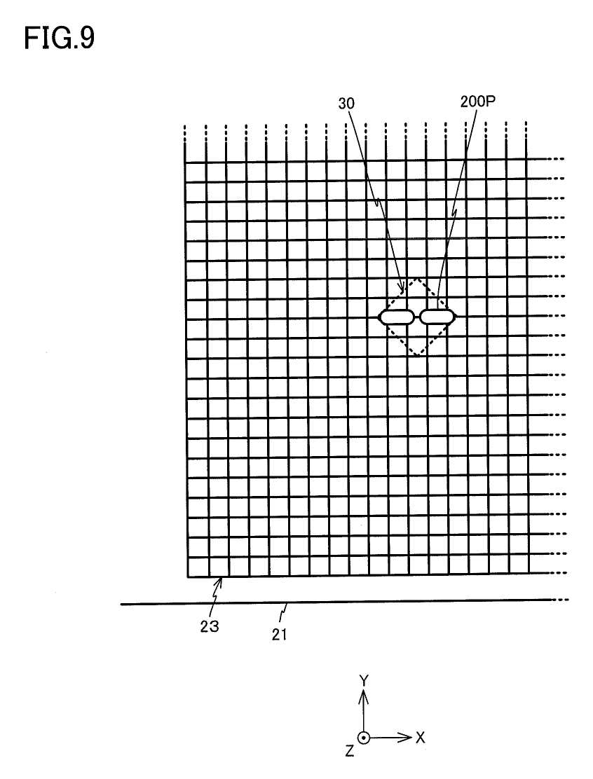

First, the film 21 to form the assembly 100 is prepared. Next, as illustrated in FIG. 8, the conductor layer 23 in a mesh shape is formed by subtract scheme or by additive scheme on the surface of the film 21. FIG. 9 is a diagram illustrating a part of conductor layer 23 in an enlarged manner. As illustrated in FIG. 9, in the conductor layer 23 at this time, portions that become the mesh patterns 231 to 234 are integrally formed with each other. Moreover, the connection pads 200P are formed on the conductor layer 23 at the locations where the respective light emitting elements 30 are mounted.

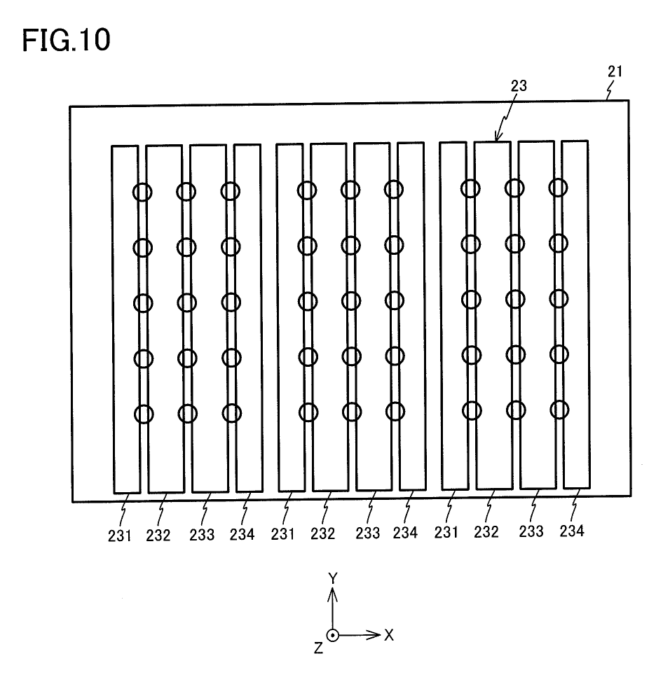

Next, the mesh patterns 231 to 234 are formed by cutting the conductor layer 23 using energy beams like laser lights. The conductor layer 23 is cut by emitting the laser lights to the conductor layer 23 formed on the surface of the film 21, and by moving the laser spot of the laser lights along the dashed lines illustrated in FIG. 8. Hence, the conductor layer 23 is cut along the dashed lines, and as illustrated in FIG. 10, the rectangular mesh patterns 231 to 234 are formed.

When the laser spot of the laser lights moves along the dashed lines illustrated in FIG. 8 on the surface of the conductor layer 23, the nearby portion to the moving path of the laser spot is melted and sublimated. Hence, as illustrated in FIG. 10, the mesh patterns 231 to 234 are cut out, while the connection pads 200P formed adjacent to each other are electrically separated from each other. According to the light emitting module 10, pairs of connection pads 200P are formed in locations indicated by circles in FIG. 10.

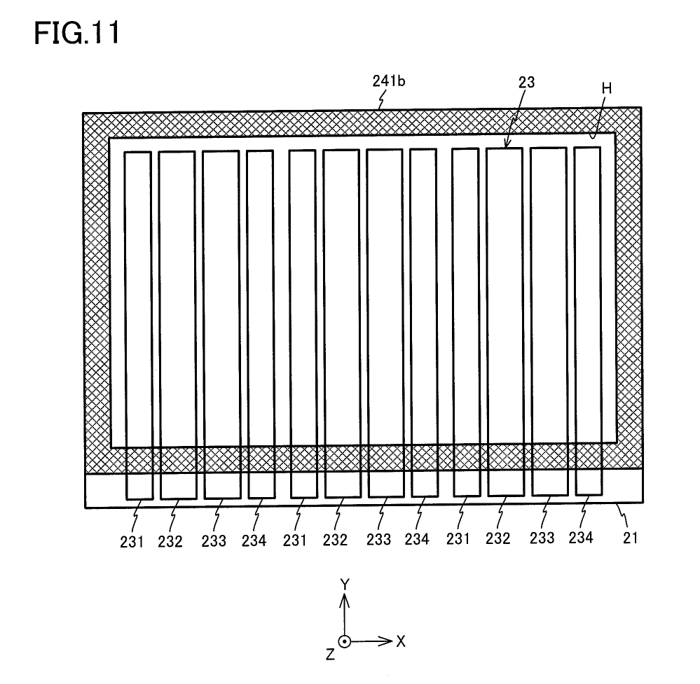

Next, as illustrated in FIG. 11, a resin sheet 241b formed in a frame shape with the lengthwise direction parallel to the X-axis direction is placed so as to surround the mesh patterns 231 to 234. This resin sheet 241b is formed of the resin 24b. The length of the resin sheet 241b in the X-axis direction is equal to the length of the film 21 in the X-axis direction. In contrast, the length of the resin sheet 241b in the Y-axis direction is shorter than the length of the film 21 in the Y-axis direction. The resin sheet 241b is placed in such a way that the outer edge at the +Y side matches the outer edge of the film 21. Accordingly, the respective ends of the mesh patterns 231 to 234 at the −Y side are exposed from the resin sheet 241b at the −Y side. Next, the major portions of the mesh patterns 231 to 234 are exposed from a rectangular opening H of the resin sheet 241b.

The resin sheet 241b is formed of a primary component that is thermosetting and transmissive to visible light. An example resin sheet 241b applicable is a sheet formed of a polyester-based resin. The resin sheet 241 has the lowest melt viscosity before curing which is within a range between, for example 10 to 10000 Pa·s, and a temperature Mp when the viscosity of the resin sheet 241b that becomes the lowest melt viscosity is, for example, equal to or higher than 160° C. It is preferable that the glass transition temperature of the resin sheet 241b should be equal to or higher than, for example, 110° C.

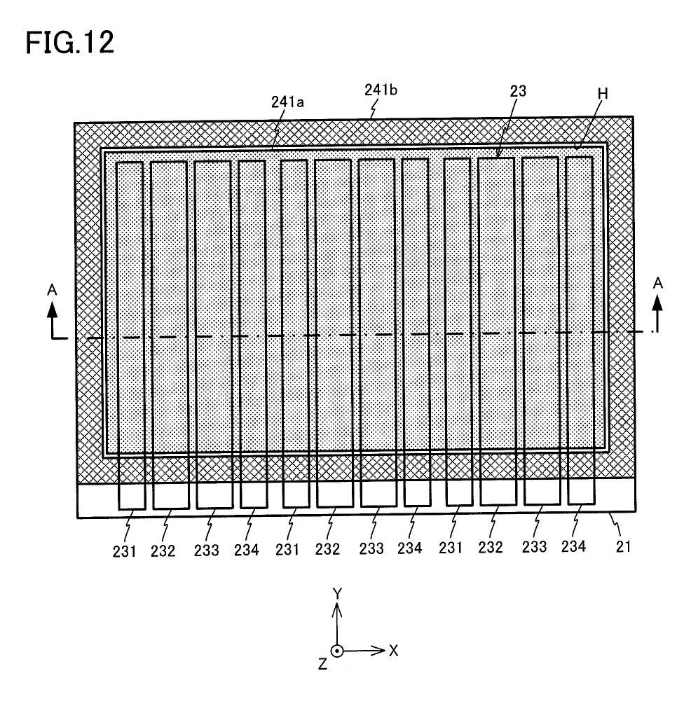

Next, as illustrated in FIG. 12, a resin sheet 241a formed in a rectangular shape with the lengthwise direction parallel to the X-axis direction is placed in the opening H of the resin sheet 241b. The resin sheet 241a is formed of the resin 24a. The resin sheet 241a is slightly smaller than the opening H of the resin sheet 241b. Hence, when the resin sheet 241a is placed in the opening H, a clearance is provided between the resin sheet 241a and the resin sheet 241b.

The resin sheet 241a is formed of a primary component that is a resin which is thermosetting and transmissive to visible light. An example resin sheet 241a applicable is a sheet formed of an epoxy-based resin.

The resin sheet 241a has the lowest melt viscosity before curing which is within a range between, for example 10 to 10000 Pa·s, and a temperature Mp when the viscosity of the resin sheet 241a becomes the lowest melt viscosity is 80 to 160° C. When the resin sheet 241a is subjected to a temperature rise from a room temperature to the temperature Mp, the melt viscosity change rate of the resin sheet 241a is equal to or smaller than 1/1000. The vicat softening temperature of the resin sheet 241a that is cured after becoming the lowest melt viscosity by heating is within a range between 80 to 160° C. According to the resin sheet 241a, the tensile storage elastic modulus when the temperature is within a range between 0 to 100° C. is within a range between 0.01 to 1000 GPa. The glass transition temperature of the resin sheet 241a is 100 to 160° C.

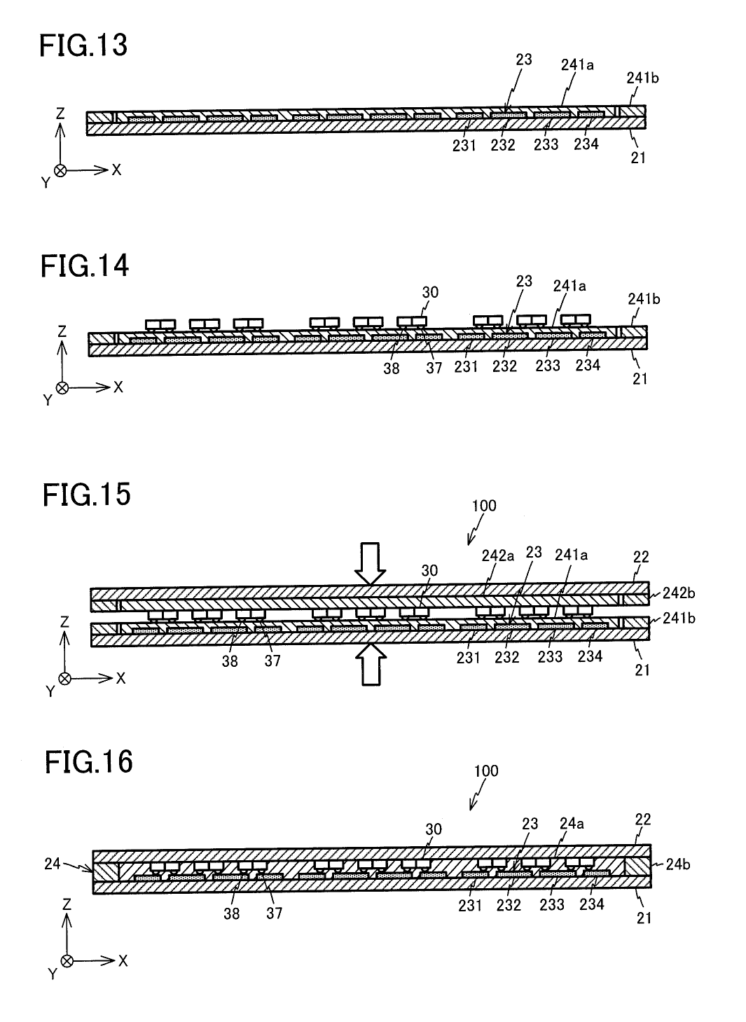

FIG. 13 is a side view illustrating the resin sheet 241a and the resin sheet 241b placed on the upper surface of the film 21. As illustrated in FIG. 13, the resin sheet 241b and the resin sheet 241a have substantially equal thickness, and is, for example, substantially 60 μm.

Next, as illustrated in FIG. 14, the light emitting element 30 is placed on the upper surface of the resin sheet 241a. At this time, the light emitting element 30 is positioned in such a way that the connection pads 200P formed on the mesh patterns 231 to 234 are located right under the bumps 37 and 38 of the light emitting element 30.

Next, as illustrated in FIG. 15, the film 22 having the resin sheets 242a and 242b pasted on the lower surface is placed on the upper-surface side of the film 21. The size and material of the resin sheet 242a are the same as those of the resin sheet 241a. Moreover, the size and material of the resin sheet 242b are the same as those of the resin sheet 241b. The thickness of the resin sheets 242a and 242b is substantially 60 μm. By placing the film 21, the assembly 100 that has the respective members, such as the films 21 and 22, tentatively assembled is formed.

Next, the assembly 100 that is tentatively assembled is heated and pressurized under a vacuum atmosphere, thereby bonding the films 21 and 22 to each other by the resin. More specifically, the assembly 100 is pressurized and heated until it reaches a temperature T1 (° C.). The temperature T1 is, when the temperature (softest temperature) at which the viscosity of the resin sheets 241a and 242a becomes the lowest melt viscosity is Mp (° C.), a temperature that satisfies the following conditional equation (1). Note that it is preferable that the temperature T1 should satisfy the following conditional equation (2). The temperature T1 may be substantially 110° C.

Mp−50° C.≤T1<Mp (1)

Mp−30° C.≤T1<Mp (2)

Moreover, Mp −10° C.≤T1<Mp may be adopted.

By performing thermal press on the assembly 100 at the temperature T1 as described above, the bumps 37 and 38 of the light emitting element 30 become in contact with the conductor layer 23 without a positional displacement.

Next, the assembly 100 is pressurized and heated until it reaches the temperature T2 (° C.). The temperature T2 is a temperature that satisfies the following conditional equation (3). Note that it is preferable that the temperature T2 should satisfy the following conditional equation (4). The temperature T2 may be substantially 130° C.

Mp≤T2<Mp+50° C. (3)

Mp+10° C.≤T2<Mp+30° C. (4)

By performing thermal press on the assembly 100 at the temperature T2 as described above, the resin sheets 241a and 242a are filled around the bumps 37 and 38 and pads 35 and 36 of the light emitting element 30, and between the surface of the light emitting element 30 and the films 21 and 22. Moreover, as illustrated in FIG. 16, the resin sheets 241a, 242a, 241b, and 242b are joined and integrated together, and thus the resin layer 24 is formed. The resin layer 24 integrates the films 21 and 22 and the light emitting elements 30 together.

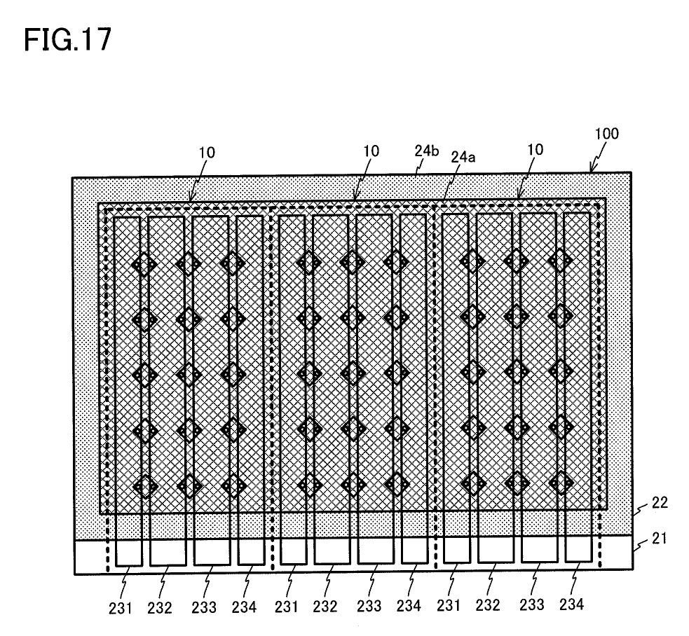

Moreover, the resin sheets 241b and 242b placed so as to surround the resin sheets 241a and 242a is formed of the resin 24b. Hence, as illustrated in FIG. 6, at the temperature between the temperature T1 and the temperature T2, the resin sheets 241b and 242b have the viscosity which is equal to or higher than P1, and which is high in comparison with the resin sheets 241a and 242a formed of the resin 24a, and no fluidization occurs. Accordingly, even if the resin sheets 241a and 242a illustrated in FIG. 15 are softened, the resin sheets 241b and 242b maintain the high viscosity. Therefore, when the thermal press is performed on the assembly 100, the resin sheets 241b and 242b prevent the softened resin sheets 241a and 242a from flowing out to the exterior. The assembly 100 is further heated substantially to the temperature T3 that is equal to or lower than the melting point of the films 21 and 22 after heated to the temperature T2. This causes the resin sheets 241a and 242a to be thermally cured, and thus the resin layer 24 is formed. Next, as illustrated in FIG. 17, the assembly 100 that has the films 21 and 22 and the light emitting element 30 integrated together is accomplished.

The light emitting module 10 illustrated in FIG. 1 is accomplished by cutting this assembly 100 along the dashed lines illustrated in FIG. 17.

As described above, according to this embodiment, when the assembly 100 from which the light emitting module 10 is to be cut out is manufactured by thermal press, the flow-out of the resin 24a that forms the resin layer 24 is prevented. This prevents a positional displacement of the light emitting element 30 originating from the flow-out of the resin 24a. Therefore, the light emitting module 10 can be manufactured highly precisely.

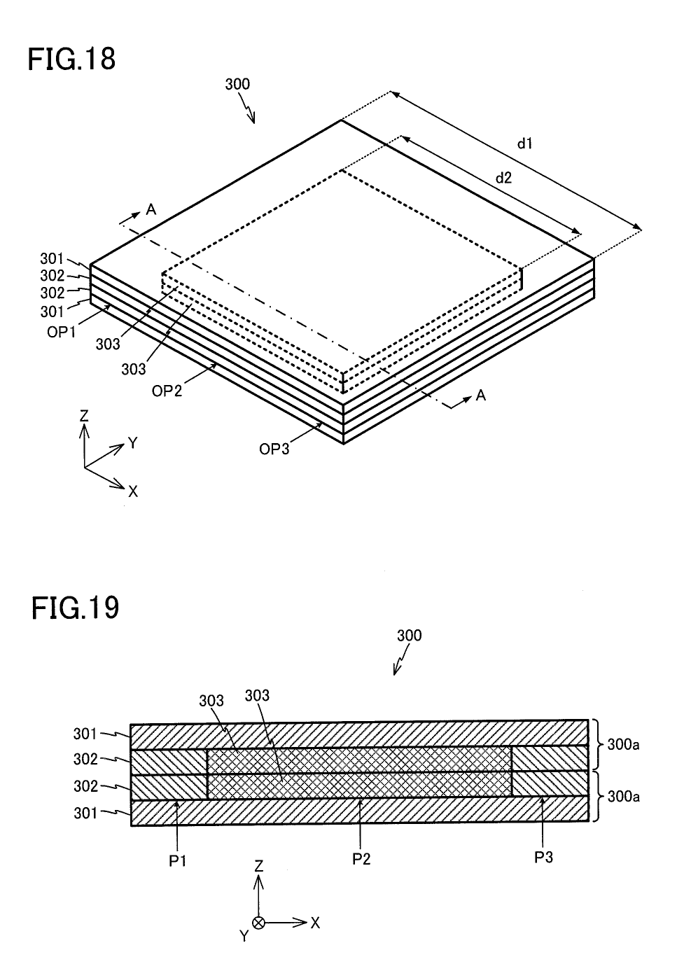

The inventors of the present disclosure evaluated the tolerability of the resin 24b that prevents the resin 24a from flowing out. FIG. 18 is a perspective view illustrating an evaluation model 300 applied for the above-described evaluation. The evaluation model 300 includes a pair of resin films 301, a pair of dam members 302, and a pair of intermediate resin sheets 303.

FIG. 19 is a diagram illustrating an AA cross-section of the evaluation model 300 in FIG. 18. As illustrated in FIG. 19, the evaluation model 300 includes a pair of sheet member sets 300a each including the resin film 301, the dam member 302, and the intermediate resin sheet 303.

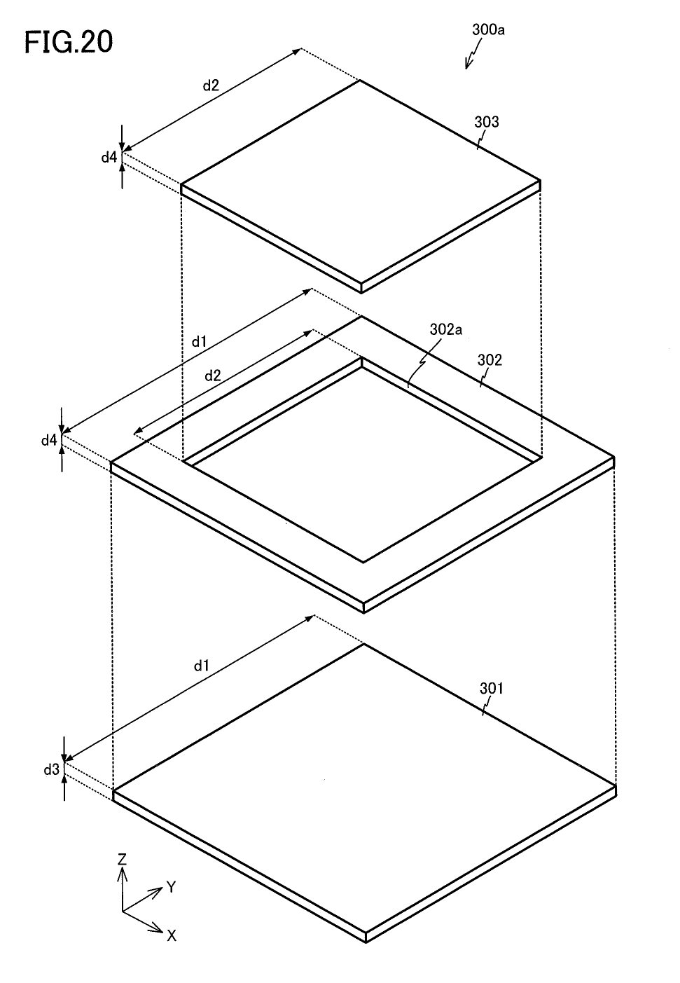

FIG. 20 is an exploded perspective view of the sheet member 300a. As illustrated in FIG. 20, the resin film 301 is a square film. A dimension d1 of the resin film 301 in the X-axis direction and in the Y-axis direction is 15 cm. Moreover, a thickness d3 of the resin film 301 is 100 μm. The resin film 301 is formed of the same material as those of the films 21 and 22 that form the light emitting module 10.

The dam member 302 is in a square frame shape. The dimension of the dam member 302 in the X-axis direction and in the Y-axis direction is equal to the dimension d1 of the resin film 301. A square opening 302a is formed in the center part of the dam member 302. A dimension d2 of the opening 302a in the X-axis direction and in the Y-axis direction is 10 cm. Moreover, a thickness d4 of the dam member 302 is 60 μm. The dam members 302 is formed of a thermoplastic resin unlike the resin 24b. Hence, the viscosity of the dam member 302 decreases as the temperature rises.

The intermediate resin sheet 303 is a square film. The dimension of the intermediate resin sheet 303 in the X-axis direction and in the Y-axis direction is equal to the dimension d2 of the opening 302a in the X-axis direction and in the Y-axis direction and formed in the dam member 302. Moreover, the thickness of the intermediate resin sheet 303 is equal to the thickness d4 of the dam member 302. The intermediate resin sheet 303 is formed of a thermosetting resin like the resin 24a.

As is clear from FIG. 20, the sheet member 300a can be formed by bonding the dam member 302 to the resin film 301, and bonding the intermediate resin sheet 303 to the resin film 301 via the opening 302a of the dam member 302. As illustrated in FIG. 19, the set of sheet member 300a formed as described above is integrated by bonding the dam member 302 and intermediate resin sheet 303 together. Accordingly, the evaluation model 300 is formed.

According to the evaluation model 300, the dam member 302 is formed of a thermoplastic resin. Accordingly, when the temperature at the time of thermal press on the evaluation model 300 rise, the dam member 302 that forms the evaluation model 300 becomes soft as the temperature rises. The inventors of the present disclosure observed how the dam member 302 became soft by gradually increasing the temperature when the thermal press was performed.

More specifically, like the thermal press on the assembly 100, a primary press was performed by pressurizing and heating the evaluation model 300 to the temperature T1. Next, a secondary press was performed by pressurizing and heating the evaluation model 300 to a target temperature. The target temperature in this case was T3 (150° C.), T4 (180° C.), T5 (200° C.), and T6 (220° C.). Moreover, a surface pressure at the time of the thermal press was substantially 0.05 MPa.

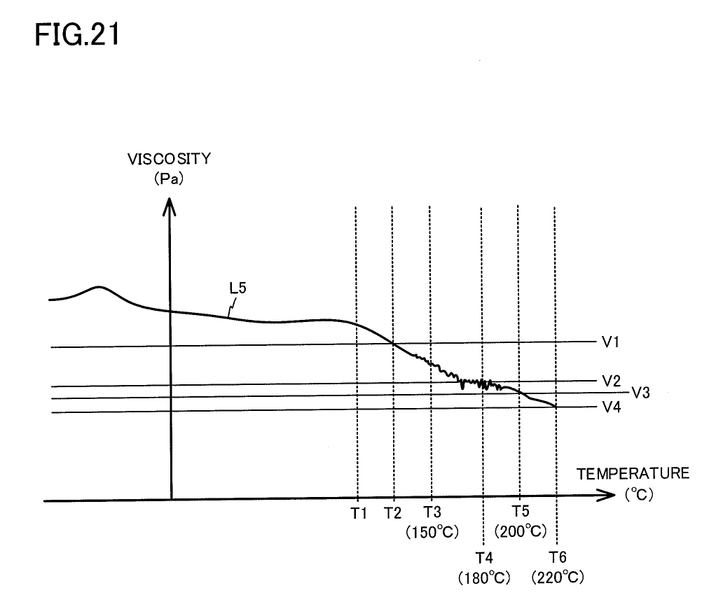

FIG. 21 is a diagram for describing the viscosity of the dam member 302. A curved line L5 in the figure indicates the relationship between the viscosity of the dam member 302 and the temperature thereof.

In the evaluation for the evaluation model 300, first, a length of the resin leaked out in the −Y direction from observation points OP1 to OP3 indicated by arrows in FIG. 18 was measured when a thermal press was performed at the upper-limit temperature T3 (150° C.). This resin was to form the dam member 302. Next, the length of the resin leaked out in the −Y direction from the observation points OP1 to OP3 indicated by arrows in FIG. 18 was measured when the thermal press was performed at the respective upper-limit temperatures T4 (180° C.), T5 (200° C.), and T6 (220° C.) in sequence.

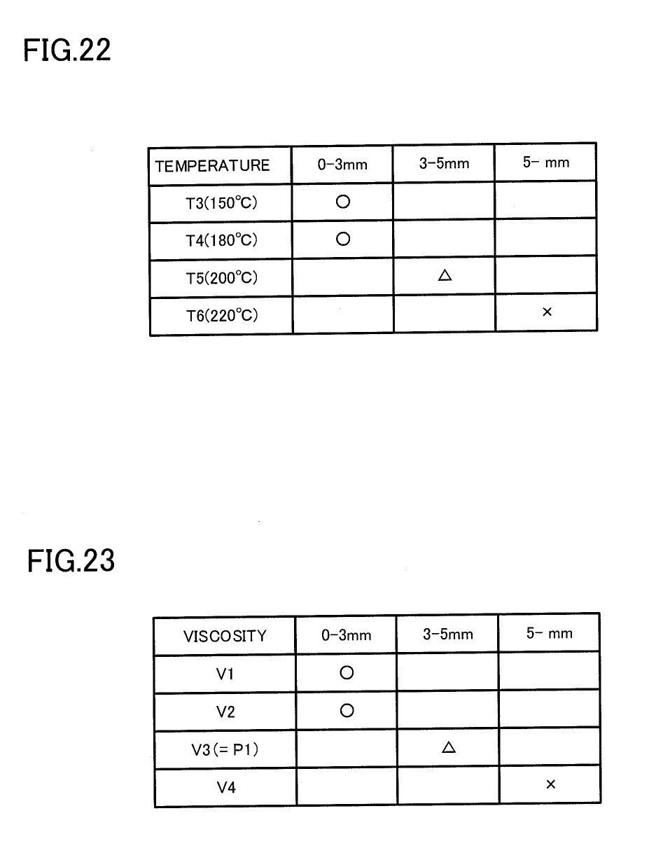

A table illustrated in FIG. 22 indicates the amount (mm) of the resin (flown resin) that flowed out horizontally from the observation points OP1 to OP3 in the −Y direction when the thermal press was performed on the evaluation model 300 at the respective temperatures T3 and T4. The amount of the flown resin when the temperature of the evaluation model 300 was raised to the temperature T3 and T4 and when the thermal press was performed was less than 3 mm. Moreover, the amount of the flown resin when the temperature of the evaluation model 300 was raised to the temperature T5 and when the thermal press was performed was equal to or greater than 3 mm but less than 5 mm, and the amount of the flown resin when the temperature of the evaluation model 300 was raised to the temperature T6 and when the thermal press was performed was equal to or greater than 5 mm. When the amount of the flown resin become equal to or greater than 3 mm, the dam member 302 was softened and collapsed, and the dam member 302 became unable to prevent the surrounded resin from flowing out.

As is clear from FIG. 21, the viscosity of the dam member 302 when the temperature of the thermal press was set to T3 to T6 was V1 to V3, respectively. The magnitude of V3 is substantially 1.0×10⁴ (Pa), and is equal to the magnitude of P1 in FIG. 6. Moreover, when FIG. 21 is taken into consideration, the relationship between the viscosities V1 to V3 and the amounts (mm) of the flown resin becomes a relationship illustrated in FIG. 23. According to the result illustrated in FIG. 23, it becomes clear that, when the viscosity of the dam member 302 is equal to or greater than the viscosity V3, i.e., when the viscosity of the dam member 302 is equal to or greater than 1.0×10⁴ (Pa), the amount of the flown resin is suppressed to be less than 3 mm.

During the manufacturing of the light emitting module 10 according to this embodiment, the thermal press is performed at the temperature substantially up to the temperature to T3 (=150° C.). At this time, the viscosity of the resin sheets 241b and 242b corresponding to the dam member 302 of the evaluation model 300 is equal to or greater than 1.0×10⁴ (Pa). Accordingly, it is apparent that, in the manufacturing of the light emitting module 10, the resin sheets 241b and 242b do not collapse but prevent the resin sheet 241a from flowing out. Therefore, the light emitting module 10 can be manufactured highly precisely.

According to this embodiment, when the thermal press is performed, the resin 24a is prevented from flowing out between the films 21 and 22. Hence, the resin layer 24 that has a uniform thickness can be formed. Accordingly, the light emitting module 10 that has uniform shape and flexibility can be manufactured highly precisely.

According to this embodiment, as illustrated in FIG. 4, the resin 24b is placed along the conductor layer 23 that is exposed to the exterior. Accordingly, by selecting the material of the resin 24b in accordance with the application of the light emitting module 10, the bonding strength between the end of the film 22 at the −Y side and the film 21 can be enhanced by the resin 24b.

Although the embodiment has been described above, the present disclosure is not limited to the above-described embodiment. For example, in the above-described embodiment, when the resin layer 24 is formed, the resin sheet 241a and the resin sheet 242a are applied to form the resin layer 24. The present disclosure is not limited to this case, and only the resin sheet 241a may be applied to form the resin layer 24.

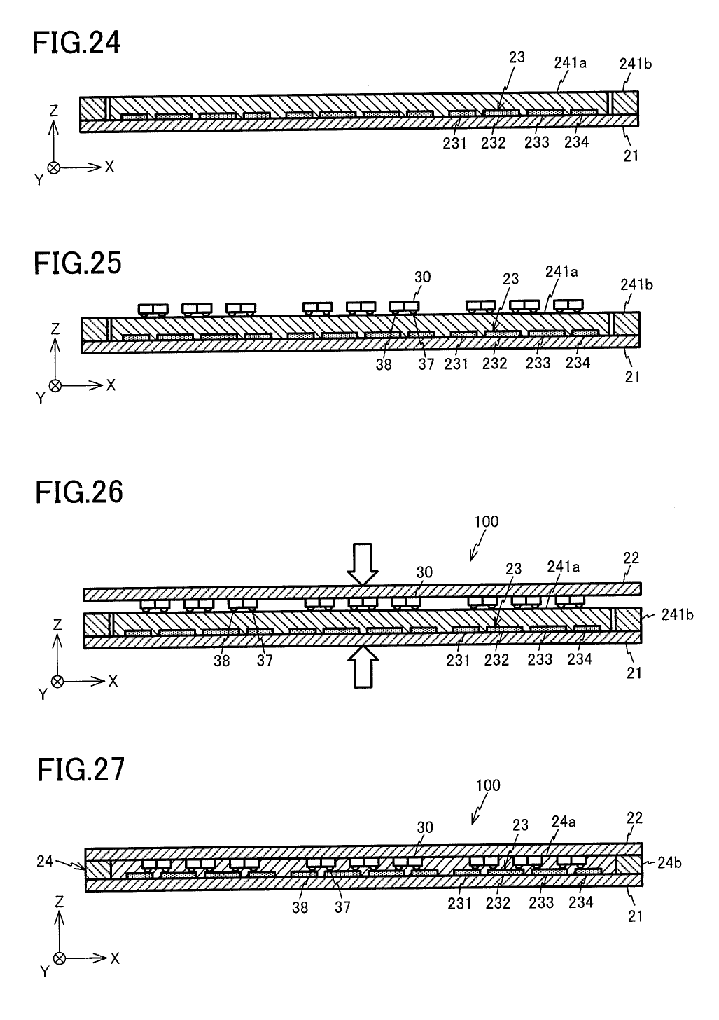

FIG. 24 is a side view illustrating the resin sheet 241a and the resin sheet 241b placed on the upper surface of the film 21. When the resin layer 24 is to be formed by applying only the resin sheet 241a, the thickness of the resin sheet 241a and the resin sheet 241b is, for example, 120 μm. The thickness of the resin sheet 241a is substantially equivalent to the height of the light emitting element 30 including the bumps 37 and 38.

Next, as illustrated in FIG. 25, the light emitting elements 30 are placed on the upper surface of the resin sheet 241a. The light emitting element 30 is positioned in such a way that the connection pads 200P formed on the mesh patterns 231 to 234 are located right under the bumps 37 and 38 of the light emitting element 30. Next, as illustrated in FIG. 26, the film 22 is placed at the upper-surface side of the film 21. By placing the film 21, the assembly 100 that has the respective components, such as the films 21 and 22, are tentatively assembled is formed.

Next, the assembly 100 that is tentatively assembled is pressurized and heated until it reaches the temperature T1 (° C.). Subsequently, the assembly 100 is pressurized and heated until it reaches the temperature T2 (° C.). As described above, by performing the thermal press on the assembly 100, the bumps 37 and 38 of the light emitting element 30 contact the conductor layer 23 without a positional displacement. Moreover, the resin sheet 241a is filled around the bumps 37 and 38 of the light emitting element 30, the circumference of the pads 36 and 35, and between the surface of the light emitting element 30 and the films 21 and 22. Furthermore, as illustrated in FIG. 21, the resin sheets 241a and 241b are joined and integrated, and thus the resin layer 24 is formed. The resin layer 24 integrates the films 21 and 22 and the light emitting elements 30 together.

For example, as illustrated in FIG. 17, by cutting the assembly 100 manufactured as described above along the dashed lines, the light emitting modules 10 illustrated in FIG. 1 are accomplished.

In the above-described embodiment, the description has been given of an example case in which the resin layer 24 is formed of the resin 24a and 24b that are thermosetting. However, the present disclosure is not limited to this case, and the resin 24a and 24b may be a thermoplastic resin. In this case, the resin sheets 241a and 242a applied when the resin layer 24 is to be formed is formed of a thermoplastic resin.

An example thermoplastic resin is a thermoplastic elastomer. Elastomer is an elastic body of a polymeric material. Example known elastomers are acrylic elastomer, olefin-based elastomer, styrene-based elastomer, ester-based elastomer, ester-based elastomer, and urethane-based elastomer.

The above-described thermoplastic resin has, for example, a vicat softening temperature within a range between 80 160° C., and has a tensile storage elastic modulus within a range between 0.01 to 10 GPa at a temperature between 0 to 100° C. A thermoplastic resin does not melt at the vicat softening temperature, and the tensile storage elastic modulus at the vicat softening temperature is equal to or greater than 0.1 MPa. The melting temperature of a thermoplastic resin is equal to or higher than 180° C. or is higher than the vicat softening temperature by equal to or higher than 40° C. The glass transition temperature of thermoplastic resin is equal to or lower than −20° C.

As illustrated in, for example, FIG. 15, in the above-described embodiment, the description has been given of an example case in which, during the manufacturing of the assembly 100, the resin sheet 241b formed of the thermosetting resin 24b is placed so as to surround the resin sheets 241a and 242a formed of the resin 24a. The present disclosure is not limited to this case, and the resin sheet 241b formed of a resin like PET that has a higher viscosity than the viscosity of the resin 24a when the thermal press is performed may be placed.

In this case, also, when the assembly 100 is manufactured by thermal press, the resin 24a that forms the resin layer 24 can be prevented from flowing out. Therefore, the light emitting module 10 can be manufactured highly precisely.

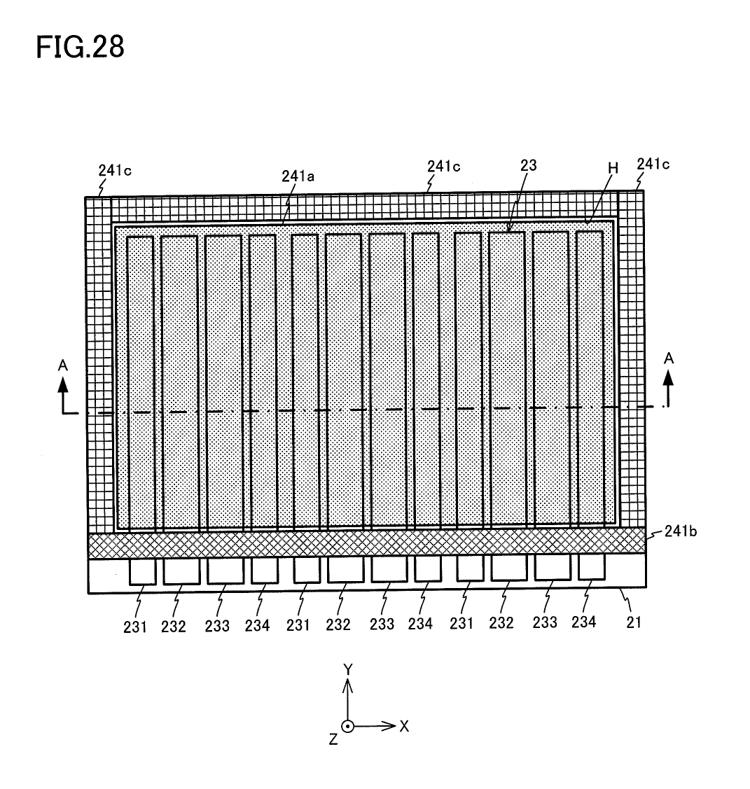

Moreover, as illustrated in FIG. 28, a tape 241c formed of PET, etc., may be placed along the outer edge of the assembly 100, and the resin sheet 241b may be placed at a location where the conductor layer 23 overlaps so as to surround the resin sheets 241a and 242a. In this case, by cutting out the light emitting modules 10 from the assembly 100, the tape 241c is separated from the light emitting module 10. Therefore, the light emitting module 10 illustrated in FIG. 1 can be manufactured.

The tape 241c illustrated in FIG. 28 does not form the light emitting module 10. Accordingly, instead of the tape 241c, a tape that does not melt like a metal tape may be applied. The portion where the tape 241c is placed is discarded after the light emitting modules 10 are cut out. In view of this point, it is preferable to apply inexpensive tape 241c.

In the above-described embodiment, the description has been given of an example case in which the three light emitting modules 10 are cut out from the assembly 100. The present disclosure is not limited to this case, and equal to or greater than four light emitting modules 10 may be obtained from the assembly 100, or equal to or smaller than two light emitting modules 10 may be obtained.

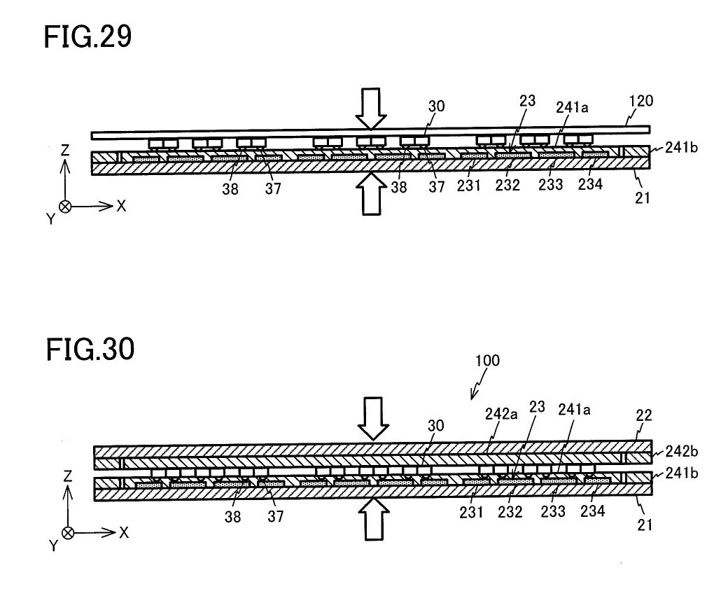

In the above-described embodiment, as illustrated in FIGS. 14 and 15, the light emitting elements 30 are placed on the upper surface of the resin sheet 241a, and the film 22 that has the resin sheets 242a and 242b pasted on the lower surface without thermal press is placed on the upper-surface side of the film 21. The present disclosure is not limited to this case, and as illustrated in FIGS. 29 and 30, instead of the film 22, a press plate 120 may be placed at the upper-surface side of the film 21, and thermal press is performed on the press plate 120 against the film 21 to connect the bumps 37 and 38 of the light emitting element 30 to the mesh patterns 231 to 234 beforehand.

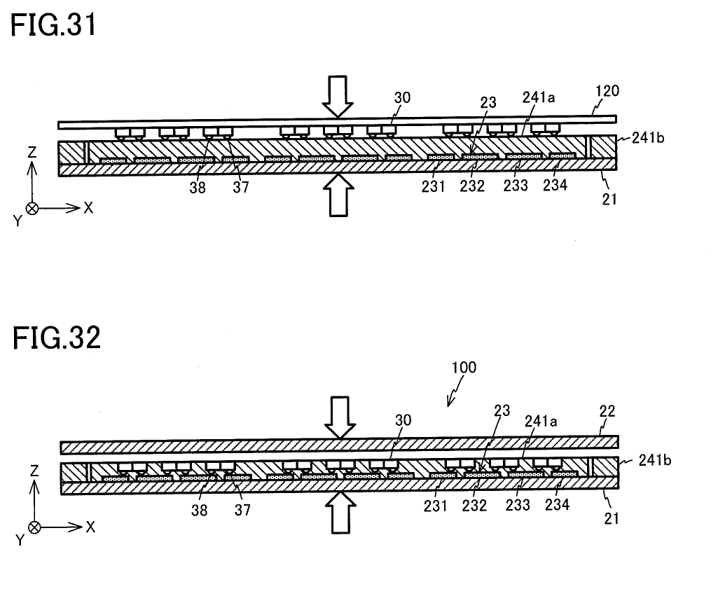

Moreover, in the above-described modified example, as illustrated in FIGS. 25 and 26, the light emitting elements 30 are placed on the upper-surface side of the resin sheet 241a, and the film 22 is placed at the upper-surface side of the film 21 without thermal press. The present disclosure is not limited to this case, and as illustrated in FIGS. 31 and 32, instead of the film 22, the press plate 120 is placed at the upper-surface side of the film 21, and thermal press is performed on the press plate 120 against the film 21 to connect the bumps 37 and 38 of the light emitting element 30 to the mesh patterns 231 to 234 beforehand. The above-described thermal press is performed at a temperature lower than the temperature at which the resin sheet 241a is thermally cured. Hence, when the subsequent process starts, the resin sheet 241a is in a state before curing. Therefore, as illustrated in FIG. 32, when thermal press is performed on the film 22 against the film 21, the resin sheet 241a firmly bonds the film 21 and 22 together.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting module comprising:
a first substrate having light transmissivity and flexibility;
a conductor layer provided on a surface of the first substrate;
a second substrate having light transmissivity and flexibility and placed so as to face the conductor layer;
a light emitting element placed between the first substrate and the second substrate, and connected to the conductor layer; and
a resin layer placed between the first substrate and the second substrate, and formed of a first resin and a second resin that have respective lowest melting viscosities different from each other.

2. A light emitting module comprising:
a first substrate having light transmissivity and flexibility;
a conductor layer provided on a surface of the first substrate;
a second substrate having light transmissivity and flexibility and placed so as to face the conductor layer;
a light emitting element placed between the first substrate and the second substrate, and connected to the conductor layer; and
a resin layer placed between the first substrate and the second substrate, and formed of a first resin and a second resin that have respective temperatures at a lowest melt viscosity different from each other.

3. The light emitting module according to claim 1, wherein the first resin is thermosetting, and a temperature of the second resin at a lowest melt viscosity is higher than a temperature of the first resin at the lowest melt viscosity.

4. A light emitting module manufacturing method comprising:
forming a conductor layer at an one side of a first substrate having light transmissivity and flexibility;
forming a surrounding layer that surrounds the conductor layer at the one side of the first substrate;
forming a first resin layer at the one side of the first substrate using a first resin, the first resin layer being laminated on the conductor layer;
placing a light emitting element on a surface of the first resin layer;
placing a second substrate having light transmissivity and flexibility at the one side of the first substrate; and
performing thermal press of heating the first substrate and the second substrate to a melting temperature at which the first resin melts, and of pressing the first substrate and the second substrate against each other.
